(19) United States
(12) Patent Application Publication
(10) Pub. No.: US 2024/0421055 A1
(43) Pub. Date: Dec. 19, 2024

(54) SEMICONDUCTOR PACKAGING WITH EMBEDDED EMF SHIELDING PROTECTION USING WIRE BONDING

(71) Applicant: STMICROELECTRONICS INTERNATIONAL N.V., Geneva (CH)

(72) Inventor: Loic Pierre Louis RENARD, Singapore (SG)

(21) Appl. No.: 18/680,178

(22) Filed: May 31, 2024

Related U.S. Application Data
(60) Provisional application No. 63/521,247, filed on Jun. 15, 2023.

(51) Int. Cl. H01L 23/498; H01L 21/48; H01L 21/56; H01L 23/00; H01L 23/31

(52) U.S. Cl. CPC H01L 23/49816; H01L 21/4853; H01L 21/565; H01L 23/3135; H01L 23/315; H01L 23/49838; H01L 23/49866; H01L 24/43; H01L 24/48; H01L 24/73; H01L 24/85; H01L 24/97; H01L 24/32; H01L 2224/32225; H01L 2224/43847; H01L 2224/48235; H01L 2224/73265; H01L 2224/85947; H01L 2224/97; H01L 2924/3025

(57) ABSTRACT

A semiconductor package with embedded electromagnetic field (EMF) shielding protection using wire bonding is provided. The semiconductor may comprise a plurality of shield wires and signal wires. The shield wires may surround all of a portion of a die to shield the die from EMF. The shield wires and the signal wires may be formed from portions of wire bonds. In manufacturing the semiconductor package these wire bonds may be created connecting to the base and/or the die. The wire bonds may then be broken to form the shield wires and signal wires. These wires may be connected to a ground plane and/or signals pads, which are separated by a dielectric material.

### CROSS REFERENCE TO RELATED APPLICATIONS

This application claims priority to U.S. Provisional Patent Application No. 63/521,247 filed on Jun. 15, 2023, which is incorporated herein by reference in its entirety.

### TECHNOLOGICAL FIELD

Example embodiments of the present disclosure relate generally to semiconductor packaging with embedded electromagnetic field (EMF) shielding protection using wire bonding.

### BACKGROUND

Semiconductor packages for electronic devices continue to shrink in size and be placed closer together. These semiconductor packages as well as other components in the electronic devices generate electromagnetic fields. Thus the semiconductor packages are being increasingly exposed to greater amounts of electromagnetic fields. Semiconductor packages may also be required to download and/or process data at increasingly faster rates. The EMF exposure may cause the semiconductor packages to malfunction and/or generate errors, including in the data downloaded and/or processed.

New systems, apparatuses, and method for semiconductor packaging are needed. The inventor have identified numerous areas of improvement in the existing technologies and processes, which are the subjects of embodiments described herein. Through applied effort, ingenuity, and innovation, many of these deficiencies, challenges, and problems have been solved by developing solutions that are included in embodiments of the present disclosure, some examples of which are described in detail herein.

### BRIEF SUMMARY

Various embodiments described herein relate to semiconductor packages, particularly semiconductor packages with embedded EMF shielding protection using wire bonding.

In accordance with some embodiments of the present disclosure, an example method is provided. The example method is of manufacturing a semiconductor package and may comprise: connecting a die to a base; creating a plurality of wire bonds each with a first end and a second end, wherein a first end of a first wire bond is connected to the die and a second end of the first wire bond is connected to the base, and wherein a first end of a second wire bond and a second end of the second wire bond are each connected to the base; applying molding to encapsulate the die and the plurality of wire bonds; removing a top side of the molding including breaking the plurality of wire bonds into a plurality of wires, wherein each of the plurality of wires is a shield wire connected to the base at a first end of the shield wire or a signal wire connected to the die at a first end of the signal wire; forming one or more redistribution layers on a first side of the molding, wherein the one or more redistribution layers include one or more signal pads and one or more ground planes, wherein each of the one or more signal pads is connected to at least one signal wires connected to the die, wherein at least one of one or more shield wires connects to the base is connected to the ground plane; applying one or more solder bumps to the one or more signal pads.

In some embodiments, the plurality of wire bonds surround the die.

In some embodiments, the plurality of wire bonds surround a portion of the dic.

In some embodiments, the semiconductor package is one of a plurality of semiconductor packages on a panel.

In some embodiments the method further comprises separating the semiconductor package from another semiconductor package of the plurality of semiconductor packages on the panel via singulation.

In some embodiments the method further comprises adjusting, prior to applying molding, an alignment of one or more of the plurality of wire bonds in a first direction.

In some embodiments the method further comprises creating, prior to forming one or more redistribution layers on a first side of the molding, one or more cavities in the molding, wherein the cavities are each associated with a signal wire connected to the die.

In some embodiments, creating one or more cavities is with laser ablation.

In some embodiments, forming one or more redistribution layers on a first side of the molding fills the one or more cavities with a conductive material.

In some embodiments, the one or more ground planes are separated from the one or more signal pads by one or more dielectric layers.

In accordance with some embodiments of the present disclosure, an example semiconductor package is provided. The example semiconductor package may comprise: a die with an active side; a base connected to a side of the die opposite the active side; a plurality of shield wires, wherein the plurality of shield wires are connected to the base and to one or more ground planes; a plurality of signal wires connected to the active side of the die and to one or more signal pads; wherein the plurality of shield wires and the plurality of signal wires are formed from portions of a plurality of wire bonds; a molding encapsulating the die, the shield wires, and the signal wires; a redistribution layer on top of the molding, wherein the redistribution layer include the one or more ground planes and the one or more signal pads; and a plurality of solder balls, wherein one or more of the plurality of solder balls are applied to the one or more signal pads.

In some embodiments, the plurality of shield wires surround the dic.

In some embodiments, the plurality of shield wires surround a portion of the die.

In some embodiments, the die is connected to the base with a gluc.

In some embodiments the semiconductor package further comprises an under bump metallization under each solder ball.

In some embodiments, the under bump metallization is comprised of nickel gold, titanium gold, or nickel palladium.

In some embodiments, a connection between at least one signal wire and the redistribution layer includes a cavity filled with a conductive material.

In some embodiments, the cavity was formed with laser ablation.

In some embodiments, at least one signal pad includes a plurality of copper layers including a first copper layer connected to a first signal wire and a second copper layer connected to the first copper layer, wherein the first copper layer has a first width, wherein the second copper layer has a second width that is larger than the first width and includes a portion of the second copper layer extending beyond the width of the first copper layer, and wherein second copper layer extending beyond the width of the first copper layer is connected to an under bump metallization associated with one of the plurality of solder balls.

In some embodiments, the one or more ground planes are separated from the one or more signal pads by one or more dielectric layers.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF SUMMARY OF THE DRAWINGS

Having thus described certain example embodiments of the present disclosure in general terms, reference will now be made to the accompanying drawings, which are not necessarily drawn to scale, and wherein:

FIG. 1 illustrates an exemplary top-view of a semiconductor package in accordance with one or more embodiments of the present disclosure;

FIG. 2 illustrates an exemplary cross-section view at the cross-section of A-A of a semiconductor package of FIG. 1 in accordance with one or more embodiments of the present disclosure;

FIG. 3 illustrates an exemplary cross-section view at the cross-section of B-B of the semiconductor package of FIG. 1 in accordance with one or more embodiments of the present disclosure;

FIG. 4 illustrates an exemplary panel of semiconductor packages in accordance with one or more embodiments of the present disclosure;

FIG. 5 illustrates an example block diagram of a flowchart of operations for manufacturing a semiconductor package in accordance with one or more embodiments of the present disclosure;

FIGS. 6A-6G illustrate exemplary views of a semiconductor package associated with the operations of FIG. 5 in accordance with one or more embodiments of the present disclosure;

FIGS. 7A-7C illustrate exemplary portions of cross-section views associated with adjustments in accordance with one or more embodiments of the present disclosure; and

FIGS. 8A-8B illustrate exemplary portion of a cross-section views associated with a cavities for wires in accordance with one or more embodiments of the present disclosure.

### DETAILED DESCRIPTION

Some embodiments of the present disclosure will now be described more fully herein with reference to the accompanying drawings, in which some, but not all, embodiments of the disclosure are shown. Indeed, various embodiments of the disclosure may be embodied in many different forms and should not be construed as limited to the embodiments set forth herein; rather, these embodiments are provided so that this disclosure will satisfy applicable legal requirements. Like reference numerals refer to like elements throughout.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in various embodiments,” “in one embodiment,” “according to one embodiment,” “in some embodiments,” and the like generally mean that the particular feature, structure, or characteristic following the phrase may be included in at least one embodiment of the present disclosure and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments or it may be excluded.

The use of the term “circuitry” as used herein with respect to components of a system or an apparatus should be understood to include particular hardware configured to perform the functions associated with the particular circuitry as described herein. The term “circuitry” should be understood broadly to include hardware and, in some embodiments, software for configuring the hardware. For example, in some embodiments, “circuitry” may include processing circuitry, communications circuitry, input/output circuitry, and the like. In some embodiments, other elements may provide or supplement the functionality of particular circuitry.

### Overview

Various embodiments of the present disclosure are directed to improved systems, apparatuses, and methods for semiconductor packages with embedded EMF shielding protection using wire bonding.

Semiconductor packages continue to shrink in size and be utilized in environments with increasing amounts of electromagnetic fields, such as in mobile phones, portable electronics, and the like. The increase in EMF exposure may cause a semiconductor package to generate errors while processing and/or transmitting data. EMF exposure may be minimized or mitigated with the semiconductor packaging with EMF shielding protection using wire bonding described herein. This may increase the performance of such semiconductor devices as well as increase the life of these semiconductor packages.

In accordance with the present disclosure, semiconductor packages have exterior wire bonds that may be broken to create two wires. Portions of the broken wire bonds may be shield wires and/or signal wires. The shield wires may be placed around an exterior portion of the semiconductor package. These shield wires may be connected a ground plane on a first side of the semiconductor package to a base on the second side of the semiconductor package. The shield wires may create a cage around all of or a portion of a die of the semiconductor package. This cage may ground signals generated by EMF the semiconductor package is exposed to. The signal wires may be connected to one or more of a plurality of signals pads to transfer signals between the die and an external device via a plurality of solder balls. Examples of the semiconductor package may be flip chips that have solder balls that connect one or more signal pads of the semiconductor device to one or more other circuitries of an electronic device.

Methods described herein are directed to manufacturing and using a semiconductor packaging with EMF shielding using wire bonds. Methods are also described herein that are directed to manufacturing a plurality of semiconductor packages using wire bonds for EMF shielding. For example, a panel of dies may be used to create a plurality of semiconductor packages that may later be separated by singulation.

### Exemplary Systems and Apparatuses

Embodiments of the present disclosure include systems and apparatuses for semiconductor packages with embedded EMF shielding protection using wire bonding as described herein and may be implemented in various embodiments.

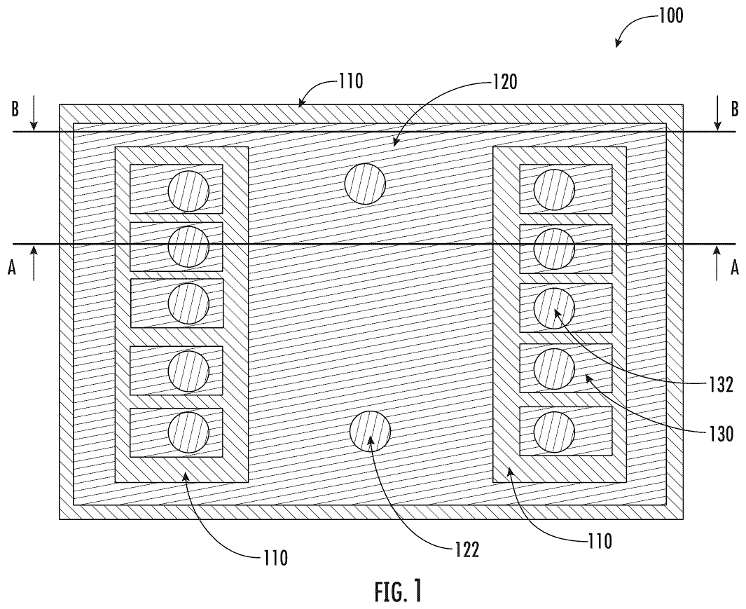

FIG. 1 illustrates an exemplary top-view of a semiconductor package in accordance with one or more embodiments of the present disclosure. A semiconductor package 100 may include a dielectric layer 110, a ground plane 120, a plurality of signal pads 130, and a plurality of solder balls, such as ground plane solder balls 122 and signal pad solder balls 132. The dielectric layer may be a polyimides (PI) and/or polybenzoxazoles (PBO) material. FIG. 1 illustrates two lines: a first line A-A and a second line B-B. Each of these lines indicates where cross-section views are taken for other figures.

It will be readily appreciated that while only one of the signal pads 130 and signal pad solder balls 132 are referenced with numbers, the semiconductor package 100 may include a plurality of each. Each of the signal pads 130 may be separated from the ground plane 120 by one or more layers and/or portions of dielectric material (e.g., dielectric layer 110). The semiconductor package 100 may be a flip chip, and when it is used in an electronic device the plurality of solder balls may connect the semiconductor package to other circuitries of the electronic device. In various embodiments, the semiconductor package 100 may be a generally square shape. It will be readily appreciated that the semiconductor package 100 may take other shapes and/or dimensions, particularly as required by an electronic device.

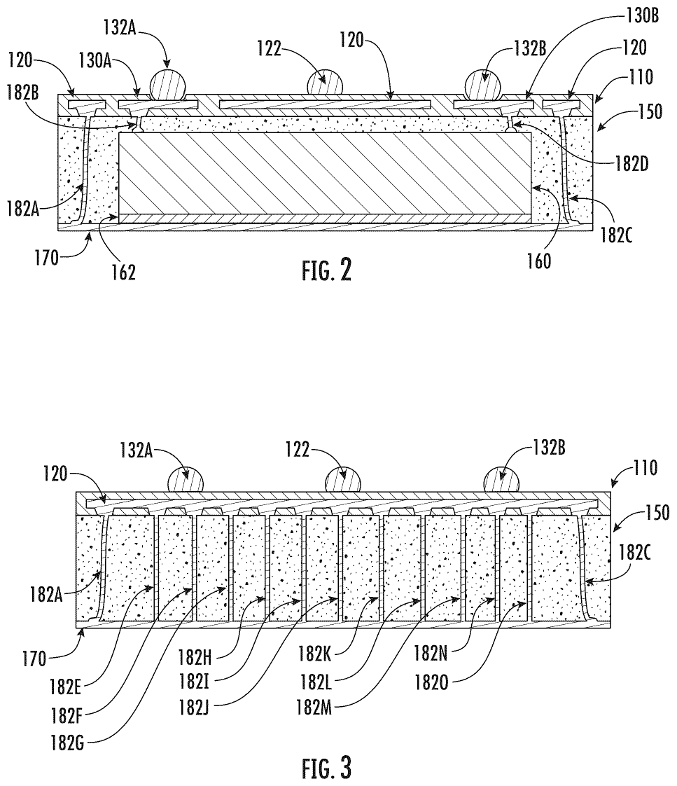

FIG. 2 illustrates an exemplary cross-section view at the cross-section of A-A of a semiconductor package of FIG. 1 in accordance with one or more embodiments of the present disclosure. The semiconductor package 100 includes a die 160 connected to a base 170 with a glue 162 or the like (e.g., tape, etc.). The glue 162 may be conductive glue or nonconductive glue, and it and may connect the die 160 to the base 170. The base 170 may, for example, be a bonding plate or have a bondable surface. In various embodiments, the base 170 may be metallic (e.g., copper, etc.) with a bondable surface. The bondable surface may have a plating on the side connected to the die, such as a nickel gold, titanium gold, nickel palladium, or the like. The signal pad solder balls 132A, 132B connect to one or more under bump metallization (UBM) layers that connects the signal pad solder balls 132 to their respective signal pads 130. The ground plane solder ball 122 is illustrated on top of the dielectric layer as it does not connect to one or more UBM layers at the cross-section of A-A.

The semiconductor package 100 includes a plurality of wires 182. As described herein, these wires 182A-D are created from wire bonds that were encapsulated in molding 150, which holds the wires 182A-D in place. Wires 182A and 182C connect the base 170 to the ground plane 120. The wires 182B and 182D connect the die 160 to a respective signal pad 130A, 130B. The wires 182B, 182D are offset from where the signal pad solder balls 132A, 132B respectively connect to the signal pads 130. In various embodiments, the wires 182B, 182D are not offset and may be aligned with where the signal pad solder balls 132A, 132B respectively connect to the signal pads 130A, 130B. Each of the signal pads 130 is formed in a redistribution layer (RDL) on top of the molding 150. The RDL includes the dielectric layer 110, the ground plane 120, and the signal pads 130. The signal pads are each connected to a solder ball 132. For example, signal pad 130A is connected to signal pad solder ball 132A and signal pad 130B is connected to signal pad solder ball 132B.

As illustrated in FIG. 2 of the cross-section of A-A of FIG. 1, wires 182A and 182C connect the ground plane 120 to the base 170. The wires 182A, 182C are examples of shield wires around the exterior of the die 160 that provide EMF shielding.

FIG. 3 illustrates an exemplary cross-section view at the cross-section of B-B of the semiconductor package of FIG. 1 in accordance with one or more embodiments of the present disclosure. This cross-section B-B is near the exterior of a first exterior side of the semiconductor package 100 and has a plurality of shield wires 182E-1820 around the first exterior side of the semiconductor package 100 that are connected to the ground plane 120 and the base 170.

In various embodiments, and as described further herein, these shield wires 182 on the exterior may formed from wire bonds either connecting the base 170 to the die 160 or connecting to base 170 at both ends of the wire bonds. The ground plane solder ball 122 and signal pad solder balls 132A, 132B are illustrated on top of the dielectric layer 110 as they do not connect to one or more UBM layers at the cross-section of B-B.

As illustrated in FIG. 3 at the cross-section of B-B of FIG. 1, wires 182A, 182C, and 182E-1820 are shield wires that connect the ground plane 120 to the base 170 that provide EMF shielding.

In various embodiments, the wires around the exterior of the semiconductor package 100 may surround a portion of the die 160 or all of the die 160.

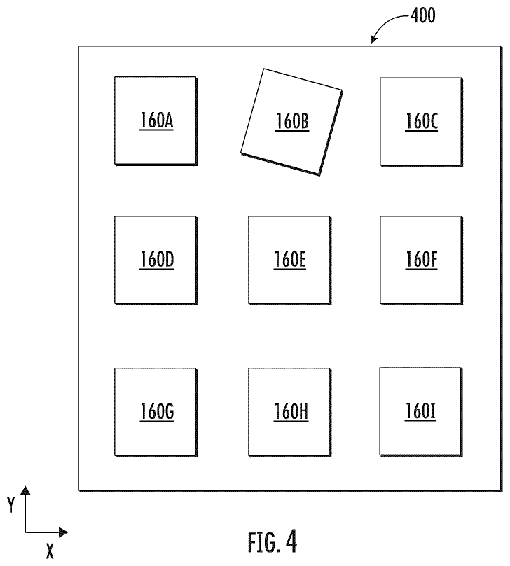

FIG. 4 illustrates an exemplary panel of die in accordance with one or more embodiments of the present disclosure. The panel 400 includes a plurality of die 160A-160I. For example, a panel may have dimensions of 600 mm by 600 mm or rectangular with dimensions of 600 mm by 700 mm, and such panels would contain a plurality of die 160. It will be appreciated that the illustration is not to scale and that more or less dies 160 may be included on a panel. It will also be appreciated that the illustration of a panel 400 may also be applicable to a wafer or the like.

As illustrated in FIG. 4, one or more of the semiconductor packages may be out of alignment. For example, semiconductor package 160B is out of alignment due to being rotated, semiconductor package 160E is out of alignment due to an offset in the Y direction, and semiconductor package 160H is out of alignment due to an offset in the X direction. It will be appreciated that the misalignments illustrated may be exaggerated.

Misalignments of the die 160 may cause a wire connecting the die 160 to the RDL 190 to be out of position as the small sizes require precision. The misalignments may cause a connection to fail or to be more likely to fail under stress. As described herein, the semiconductor packages 100 with EMF shielding using wire bonds may address and/or correct for such misalignments. This increases the yield of a panel or the like applying the present disclosure. For example, panel 400, after completion of a plurality of operations described herein, may have individual semiconductor packages 100 separated from the panel 400 with one or more singulation operations.

It should be readily appreciated that the embodiments of the systems and apparatuses, described herein may be configured in various additional and alternative manners in addition to those expressly described herein.

### Exemplary Methods

FIG. 5 illustrates an example block diagram of a flowchart of operations for manufacturing a semiconductor package in accordance with one or more embodiments of the present disclosure. In various embodiments one or more of the operations may be omitted or repeated. It will also be appreciated that other operations not described herein may also occur.

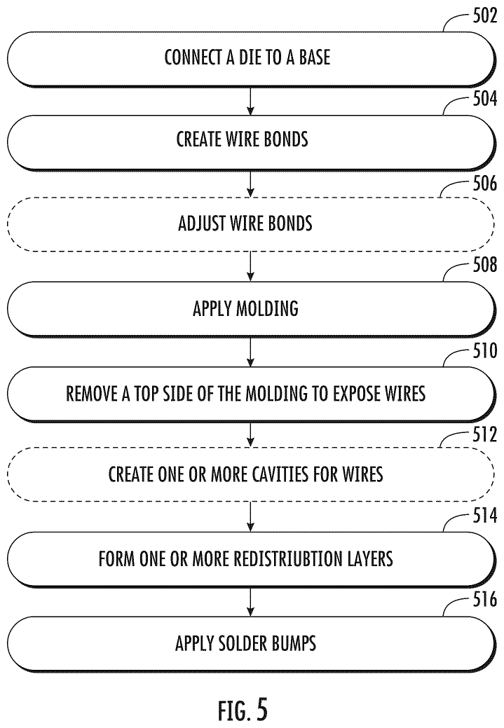

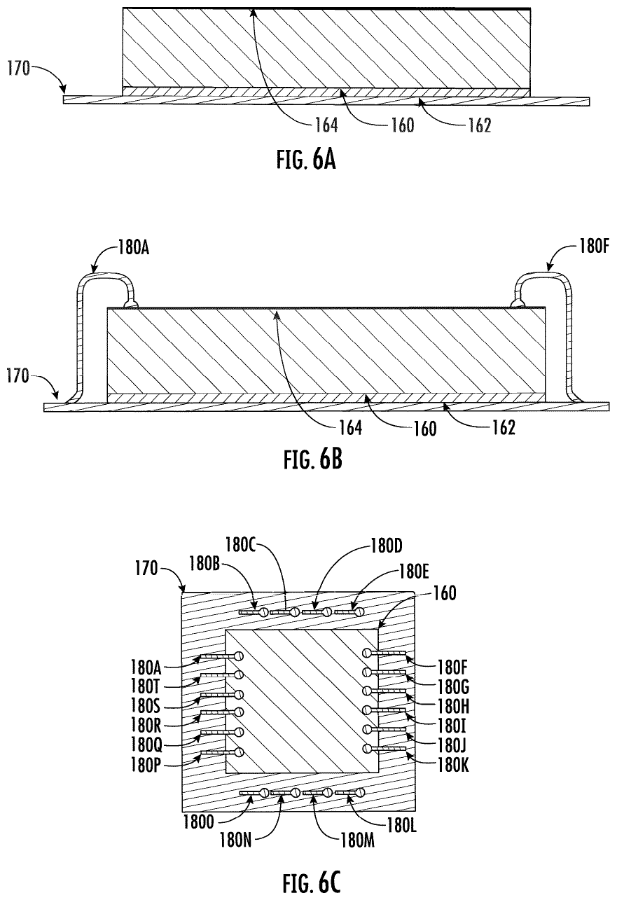

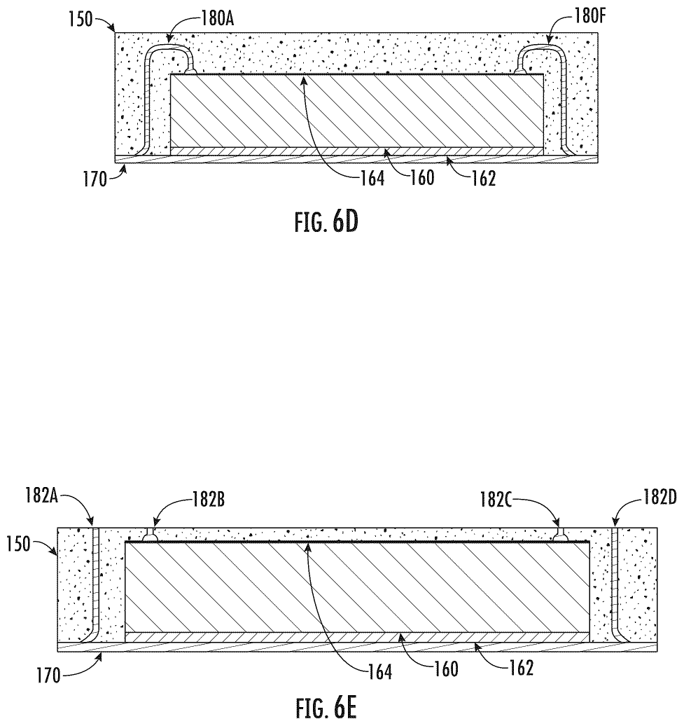

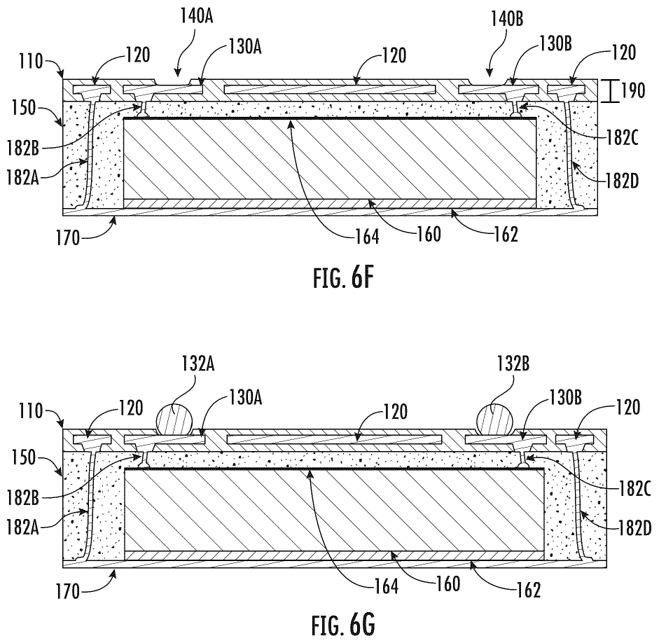

At operation 502, a die 160 is connected to a base 170. For example, a die 160 may be connected to a bondable surface of the base 170 using a glue 162 or the like. In various embodiments, a plurality of die 160 may be connected to a base 170 of a panel 400. This operation is further described in relation to FIG. 6A.

At operation 504, wire bonds are created. A plurality of wire bonds 180 are created, including one or more wire bonds 180 connecting the die 160 and the base 170 and one or more wire bonds 180 connecting both sides of the wire bond 180 to the base 170. The wire bonds 180 may be created around all of or a portion of the exterior of the die 160. This operation is further described in relation to FIGS. 6B and 6C.

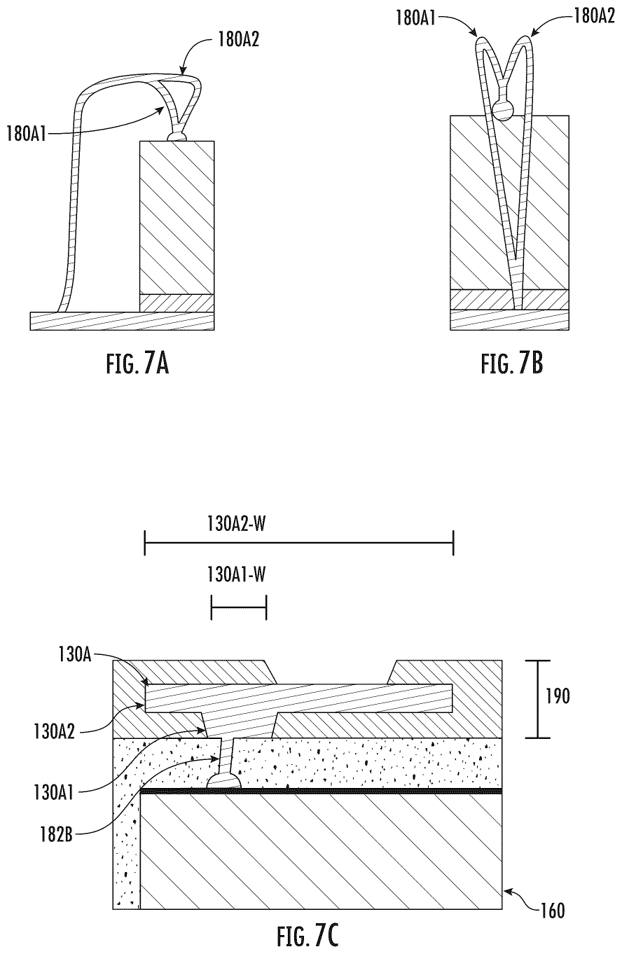

At operation 506, wire bonds may be adjusted. In various embodiments, a wire bond may be adjusted. While the adjustment of the wire bond is described as a separate operation herein, it will be appreciated that the adjustment may be performed during or contemporaneously with the creation of a wire bond. A determination may be made that one or more wire bonds 180 need to be adjusted. In various embodiments, the RDL 190 may be formed without allowing for adjustment of the location of one or more portions of the RDL 190. For example, a panel 400 with a plurality of die 160 may have an RDL 190 formed for all of the die 160 at one time. If any of the die 160 are determined to be out of alignment, these dies 160 may need to be aligned or the wire bonds 180 may be adjusted to allow for the misalignment. This operation is further described in relation to FIGS. 7A-7C.

At operation 508, molding 150 is applied. The molding 150 encapsulates the die and wire bonds 180, including being above the die 160 and wire bonds 180. The molding 150 will hold the die 160 and wire bonds 180 in place. This operation is further described in relation to FIG. 6D.

At operation 510, a top side of the molding 150 is removed to exposes wire 182. Removing the top side of the molding 150 may be done by grinding the molding 150 down so that the wire bonds 180 are broken, each of which creates two separate wires 182 from different portions of a wire bond 180. Each of these separate wires 180 may have an open end now exposed due to where the molding 150 was removed and a connected end that is connected to a die 160 for a signal wire 182 or the base 170 for a shield wire 182. This operation is further described in relation to FIG. 6E.

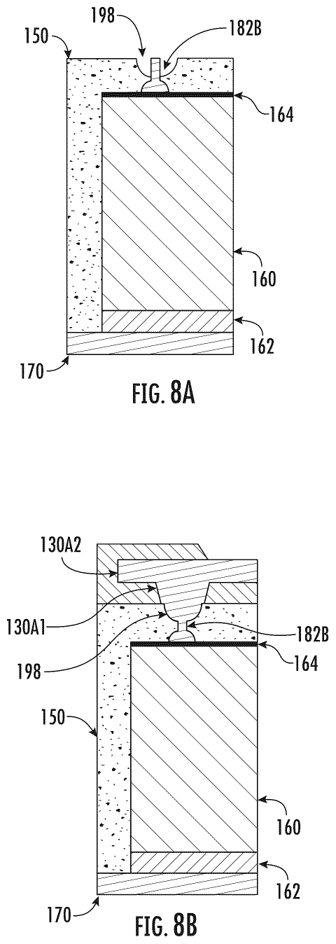

At operation 512, one or more cavities 198 may be created for the wires 182. For example, and for each of the signal wires 182 connected to the die 160, the end of the signal wire 182 not connected to the die 160 may have the molding 160 around the end portion of the wire 182 removed to create a cavity 198 in the molding 160. In various embodiments, a cavity 198 may be created by a laser, such as with laser ablation. This operation is further described in relation to FIGS. 8A-8B.

At operation 514, one or more RDL 190 may be formed. The formation of the RDL 190 may generate the dielectric layer 110, the ground plane 120, the signal pads 130, and the UBM 140. This operation is further described in relation to FIG. 6F.

At operation 516, solder bumps (e.g., 122, 132) may be applied. The solder bumps may be applied to one or more portions of the RDL 190 with UBM 140. This operation is further described in relation to FIG. 6G.

FIGS. 6A-6G illustrate exemplary views of a semiconductor package 100 associated with the operations of FIG. 5 in accordance with one or more embodiments of the present disclosure.

FIG. 6A illustrates an exemplary cross-section view of a die 160 attached to a base 170 via a glue 162, such as after the performance of operation 502. The die 160 may have an active surface 164 located on a first side opposite of the side where of the die 160 attached to the base 170. In various embodiments, the base 170 may be a portion of a panel 400, wafer, or the like.

FIG. 6B illustrates an exemplary cross-section view of a die 160 and a base 170 with a first wire bond 180A and a second wire bond 180F having been created to bond the die 160 and base 170, such as after the performance of operation 504. The wire bonds 180A, 180F rise a first distance above the die 160.

FIG. 6C illustrates a top-view of an exemplary die 160 attached to a base 170 with a plurality of wire bonds 180, such as after the performance of operation 504. A first group of the plurality of wire bonds 180 are connected to the die 160 and to the base 170 (e.g., 180A, 180F-K, and 180P-T). A second group of the plurality of wire bonds 180 are connected at both ends to the base 170 (e.g., 180B-180E and 180L-180O). As illustrated, the wire bonds 180 are located around the exterior of the die 160. In various embodiments, an alternative number of wire bonds 180 may be created and/or alternative locations for the wire bonds 180 may be used.

FIG. 6D illustrates an exemplary cross-section view of an exemplary die 160, base 170, and wire bonds 180A, 180B after a molding 150 has been applied to encapsulate the die 160 and wire bonds 180, such as after the performance of operation 508.

FIG. 6E illustrates an exemplary cross-section view after a top side of the molding 150 has been removed to expose wires 182A-182D, such as after the performance of operation 510. The removal of the molding 150 may be of an amount of molding 150 to break the wire bonds 180A to create wires 182A, 182B and the wire bond 180F to create wires 182C, 182D. Thus these wires 182A-182D no longer bond two components together. As illustrated, each of wires 182B and 182C is connected to the die 160 at a first end and exposed to a top side of the molding with a second end that is open. Also, each of wires 182A and 182D is connected to the base 170 at a first end and exposed to a top side of the molding with a second end that is open. In various embodiments, the removal of the molding 150 may be by grinding. When exposed, the wire bonds 180 become, in the illustrated embodiment, two wires: one signal wire (e.g., 182B) and one shield wire (182A).

FIG. 6F illustrates an exemplary cross-section view of the die 160, base 170, wires 182A-D, and RDL 190, such as after the performance of operation 514. The forming of one or more RDL 190 may include a plurality of operations that result in forming a plurality of layers including a conductive layer 110, a ground plane 120, and signal pads 130. The size and shape of the RDL 190 may be from the performance of these plurality of operations, which may include but are not limited to: depositing copper seed; depositing a resist; resist exposure to remove one or more portions of the resist; electrolytic copper growth; resist stripping; substrate deposition (e.g., PI and/or PBO layer deposition); and UBM 140 deposition (e.g., nickel gold, titanium gold, nickel palladium, etc.). Multiple of these operations may be iterated to form the RDL 190. The UBM 140 may be applied as copper layers of the RDL 190 may oxidize if the UBM is not applied and the copper is exposed. This oxidation may reduce the efficiency of the semiconductor package or cause malfunctions. With the forming of the RDL 190, the shield wires (e.g., 182A, 182D) are connected to the ground plane 120 and the signal wires (e.g., 182B, 182C) are each connected an associated signal pad (e.g., 130A, 130B).

The RDL 190 is separated from the die 160 with wires (e.g., 182B, 182C) connecting the die 160 to associated signal pads 130A, 130B. The separation between the RDL 190 and the die 160 by these signal wires 182B, 182D allows for improved operation of the semiconductor package due to the RDL 190 and the die 160 having different coefficient of thermal expansion. Under thermal expansion the RDL 190 and die 160 may expand or contract and cause stress on the other, which may lead to delamination and the die and/or breaking or the deterioration of a connection. The signal wires 182 of the present disclosure allows for a lowering of stresses and an increase in reliability between the RDL 190 and the die 160.

FIG. 6G illustrates an exemplary cross-section view of the die 160, base 170, wires 182A-D, RDL 190, and signal pad solder bumps 132A, 132B, such as after the performance of operation 516.

FIG. 7A-7C illustrate exemplary portions of cross-section views associated with adjustments in accordance with one or more embodiments of the present disclosure. An adjustment may allow for the change in shape, pitch, and/or angle of the wire bond 180 and the associated signal wire and shield wire created by breaking the wire bond 180.

FIG. 7A illustrates an exemplary portion of a cross-section view associated with an adjustment of a wire bond 180 in accordance with one or more embodiments of the present disclosure, such as before and after the performance of operation 516. For example, a wire bond 180A may be created with a first end connected to the die 160 and a second end connected to the base 170. While the wire bond 180A is connected in accordance with the present disclosure, the wire bond 180A may be positioned in a first position 180A1 that may be out of alignment. The misalignment of the wire bond 180A may be due to the die 160 being out of alignment. Alternatively or additionally, the misalignment of the wire bond 180A may be due the wire bond 180A shifting once created. An adjustment may be made to move the wire bond 180A from a position illustrated as 180A1 to a second position illustrated as 180A2. This adjustment may, for example, align where the end of the signal wire will be once the wire bond 180A is broken into a signal wire and a shield wire. While the adjustment of the wire bond is described as a separate operation herein, it will be appreciated that the adjustment may be performed during or contemporaneously with the creation of a wire bond.

FIG. 7B illustrates an exemplary portion of a cross-section view associated with an adjustment of a wire bond 180A in accordance with one or more embodiments of the present disclosure, such as before and after the performance of operation 516. The wire bond 180A may be adjusted to move laterally to the die 160 to adjust for a misalignment.

FIG. 7C illustrates an exemplary portion of a cross-section view associated with an adjustment of a wire bond 180 in accordance with one or more embodiments of the present disclosure. The RDL 190 of FIG. 7C may include a signal pad 130 with a first copper layer 130A1 and a second copper layer 130A2. The first copper layer 130A1 may have a width of 130A1-W and the second copper layer 130A2 may have a width of 130A2-W. In various embodiments, the wire may be 20 microns in width and the first copper layer 130A1 may be 50-60 microns in width, which allows for adjustment in the location of the wire 182B to be connected to the first copper layer 130A1 during the forming of the RDL 190. An adjustment of a wire bond 180 may allow for the movement of, for example, a signal wire 182B to connect to the first copper layer 130A1 during the forming of the RDL 190. In contrast, without such an alignment the signal wire 182B may have been positioned on its exposed side before an operation of forming RDL 190 that would have left the exposed side of the wire 182B not connected to the signal pad 130A.

An alignment operation may adjust a wire 182 for connection to the RDL layer 190. In various embodiments where multiple die 160 are prepared together in a panel 400, one or more adjustments may improve the yield of the panel 400 as the plurality of die 160 are having, for example, the RDL formed for all of the die 160 at the same time.

In various embodiments of manufacturing panels, a determination may be made if one or more die 160 are misaligned. If any die is misaligned, one or more adjustments to be made may be determined. During the manufacturing of the semiconductor packages 100, the one or more adjustments may be made.

FIG. 8A-8B illustrate exemplary portion of a cross-section views associated with cavities for wires in accordance with one or more embodiments of the present disclosure. In various embodiments, one or more cavities 198 may be created in the molding 150 for the exposed ends of signal wires (e.g., 182B). The cavity 198 may be created by using a laser, such as with laser ablation of the molding 150. The one or more cavities 198 may be created after removing a top side of the molding 150. The cavities 198 may allow for the formation of the RDL 190 to include providing additional copper connecting a wire 182B to the RDL 190 by filling the cavity 198 with copper.

FIG. 8A illustrates an exemplary portion of a cross-section view associated with a cavity 198 in accordance with one or more embodiments of the present disclosure, such as after the performance of operation 512. After a top side of the molding has been removed a cavity 198 may be created. The cavity 198 may further remove molding 150 in a specific area associated with the exposed end of a signal wire 182 or a shield wire 182. As illustrated in FIG. 8A, the signal wire 182B connects to die 160, specifically at the active side 164 of die 160. While not illustrated, it will be appreciated that a shield wire 182 connected to base 170 may also have a cavity created on its exposed end that is not connected to the base 170. In various embodiments, a cavity 198 may also be created to address a misalignment of a die 160 and/or misalignment of a wire bond 180 and/or wire 182 prior to the formation of the RDL 190.

FIG. 8B illustrates an exemplary portion of a cross-section view associated with a cavity 198 in accordance with one or more embodiments of the present disclosure, such as after the performance of operation 514. The cavity 198 has been filled with copper during the formation of the RDL 190.

In various embodiments, the filling of the cavity 198 with copper may provide for an improved connection to a wire. It may also provide improved mechanical grip and adhesion of the connection between the die 160 and the signal pad 130 (or between the base 170 and the ground plane 120 for a wire not illustrated).

### CONCLUSION

Operations and/or functions of the present disclosure have been described herein, such as in flowcharts or figures associated with flowcharts. While operations and/or functions are illustrated in a particular order, this should not be understood as requiring that such operations and/or functions be performed in the particular order shown or in sequential order, or that all illustrated operations be performed, to achieve desirable results. In certain circumstances, operations and/or functions in alternative ordering may be advantageous. In some cases, the actions recited in the claims may be performed in a different order and still achieve desirable results. Thus, while particular embodiments of the subject matter have been described, other embodiments are within the scope of the following claims.

While this specification contains many specific embodiments and implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

While this detailed description has set forth some embodiments of the present invention, the appended claims cover other embodiments of the present invention which differ from the described embodiments according to various modifications and improvements.

Within the appended claims, unless the specific term “means for” or “step for” is used within a given claim, it is not intended that the claim be interpreted under 35 U.S.C. § 112, paragraph 6.

1. A method of manufacturing a semiconductor package comprising:
connecting a die to a base;
creating a plurality of wire bonds each with a first end and a second end, wherein a first end of a first wire bond is connected to the die and a second end of the first wire bond is connected to the base, and wherein a first end of a second wire bond and a second end of the second wire bond are each connected to the base;
applying molding to encapsulate the die and the plurality of wire bonds;
removing a top side of the molding including breaking the plurality of wire bonds into a plurality of wires, wherein each of the plurality of wires is a shield wire connected to the base at a first end of the shield wire or a signal wire connected to the die at a first end of the signal wire;
forming one or more redistribution layers on a first side of the molding, wherein the one or more redistribution layers include one or more signal pads and one or more ground planes, wherein each of the one or more signal pads is connected to at least one signal wires connected to the die, wherein at least one of one or more shield wires connects to the base is connected to the ground plane;
applying one or more solder bumps to the one or more signal pads.

2. A method of manufacturing a semiconductor package of claim 1, wherein the plurality of wire bonds surround the die.

3. A method of manufacturing a semiconductor package of claim 1, wherein the plurality of wire bonds surround a portion of the die.

4. A method of manufacturing a semiconductor package of claim 1, wherein the semiconductor package is one of a plurality of semiconductor packages on a panel.

5. A method of manufacturing a semiconductor package of claim 4 further comprising:
separating the semiconductor package from another semiconductor package of the plurality of semiconductor packages on the panel via singulation.

6. A method of manufacturing a semiconductor package of claim 1 further comprising:
adjusting, prior to applying molding, an alignment of one or more of the plurality of wire bonds in a first direction.

7. A method of manufacturing a semiconductor package of claim 1 further comprising:
creating, prior to forming one or more redistribution layers on a first side of the molding, one or more cavities in the molding, wherein the cavities are each associated with a signal wire connected to the die.

8. A method of manufacturing a semiconductor package of claim 7, wherein creating one or more cavities is with laser ablation.

9. A method of manufacturing a semiconductor package of claim 7, wherein forming one or more redistribution layers on a first side of the molding fills the one or more cavities with a conductive material.

10. A method of manufacturing a semiconductor package of claim 1, wherein the one or more ground planes are separated from the one or more signal pads by one or more dielectric layers.

11. A semiconductor package comprising:
a die with an active side;
a base connected to a side of the die opposite the active side;
a plurality of shield wires, wherein the plurality of shield wires are connected to the base and to one or more ground planes;
a plurality of signal wires connected to the active side of the die and to one or more signal pads;
wherein the plurality of shield wires and the plurality of signal wires are formed from portions of a plurality of wire bonds;
a molding encapsulating the die, the shield wires, and the signal wires;
a redistribution layer on top of the molding, wherein the redistribution layer include the one or more ground planes and the one or more signal pads; and
a plurality of solder balls, wherein one or more of the plurality of solder balls are applied to the one or more signal pads.

12. The semiconductor package of claim 11, wherein the plurality of shield wires surround the die.

13. The semiconductor package of claim 11, wherein the plurality of shield wires surround a portion of the die.

14. The semiconductor package of claim 11, wherein the die is connected to the base with a glue.

15. The semiconductor package of claim 11 further comprising an under bump metallization under each solder ball.

16. The semiconductor package of claim 15, wherein the under bump metallization is comprised of nickel gold, titanium gold, or nickel palladium.

17. The semiconductor package of claim 11, wherein a connection between at least one signal wire and the redistribution layer includes a cavity filled with a conductive material.

18. The semiconductor package of claim 17, wherein the cavity was formed with laser ablation.

19. The semiconductor package of claim 11, wherein at least one signal pad includes a plurality of copper layers including a first copper layer connected to a first signal wire and a second copper layer connected to the first copper layer, wherein the first copper layer has a first width, wherein the second copper layer has a second width that is larger than the first width and includes a portion of the second copper layer extending beyond the width of the first copper layer, and wherein second copper layer extending beyond the width of the first copper layer is connected to an under bump metallization associated with one of the plurality of solder balls.

20. The semiconductor package of claim 11, wherein the one or more ground planes are separated from the one or more signal pads by one or more dielectric layers.
